(19) United States
(12) Patent Application Publication
(10) Pub. No.: US 2012/0103419 A1
(43) Pub. Date: May 3, 2012

(54) GROUP-III NITRIDE SOLAR CELLS GROWN ON HIGH QUALITY GROUP-III NITRIDE CRYSTALS MOUNTED ON FOREIGN MATERIAL

(75) Inventors: Siddha Pimputkar, Goleta, CA (US); Shuji Nakamura, Santa Barbara, CA (US); Steven P. DenBaars, Goleta, CA (US)

(73) Assignee: THE REGENTS OF THE UNIVERSITY OF CALIFORNIA, Oakland, CA (US)

(21) Appl. No.: 13/281,170

(22) Filed: Oct. 25, 2011

Related U.S. Application Data
(60) Provisional application No. 61/407,354, filed on Oct. 27, 2010.
(60) Provisional application No. 61/441,156, filed on Feb. 9, 2011.

(51) Int. Cl. H01L 31/0304; H01L 31/18

(52) U.S. Cl. 136/262; 438/93; 136/252; 257/E31.019

(57) ABSTRACT

A group-III nitride solar cell is grown on a thin piece of a group-III nitride crystal that has been mounted on a carrier comprised of a foreign material. The thin piece is a thin layer with a thickness that ranges from approximately 5 microns to approximately 300 microns.

### CROSS REFERENCE TO RELATED APPLICATION

This application claims the benefit under 35 U.S.C. Section 119(e) of the following co-pending and commonly-assigned application:

U.S. Provisional Patent Application Ser. No. 61/407,354, filed on Oct. 27, 2010, by Siddha Pimputkar, Shuji Nakamura, and Steven P. DenBaars, entitled “GROUP-III NITRIDE SOLAR CELLS GROWN ON HIGH QUALITY GROUP-III NITRIDE CRYSTALS MOUNTED ON FOREIGN MATERIAL,” attorneys' docket number 30794.398-US-P1 (2011-229-1);

which application is incorporated by reference herein.

This application is related to the following co-pending and commonly-assigned applications:

U.S. Utility patent application Ser. No. 13/279,131, filed on Oct. 21, 2011, by Robert M. Farrell, Carl J. Neufeld, Nikholas G. Toledo, Steven P. DenBaars, Umesh K. Mishra, James S. Speck, and Shuji Nakamura, entitled “III-NITRIDE FLIP-CHIP SOLAR CELLS,” attorneys' docket number 30794.388-US-U1 (2011-024-2), which application claims the benefit under 35 U.S.C. Section 119(e) of U.S. Provisional Patent Application Ser. No. 61/405,492, filed on Oct. 21, 2010, by Robert M. Farrell, Carl J. Neufeld, Nikholas G. Toledo, Steven P. DenBaars, Umesh K. Mishra, James S. Speck, and Shuji Nakamura, entitled “III-NITRIDE FLIP-CHIP SOLAR CELLS,” attorneys' docket number 30794.388-US-P1 (2011-024-1); and

U.S. Provisional Patent Application Ser. No. 61/441,156, filed on Feb. 9, 2011, by Nikholas G. Toledo, Umesh K. Mishra, Carl J. Neufeld, Samantha C. Cruz, Steven P. DenBaars, and James S. Speck, entitled WAFER BONDED III-NITRIDE AND NON-III-NITRIDE MULTI-JUNCTION SOLAR CELLS,” attorneys' docket number 30794.404-US-P1 (2011-304-1);

which applications are incorporated by reference herein.

### BACKGROUND OF THE INVENTION

1. Field of the Invention

The invention is related generally to the field of solar cells, and more particularly, to group-III nitride solar cells grown on high quality group-III nitride crystals mounted on foreign material.

2. Description of the Related Art

Currently, group-III nitride solar cells are usually grown in the c-direction on sapphire substrates. The choice of sapphire for the substrate results from the low cost and high quality of the substrate, along with the property that it is closely lattice matched to epitaxially grown group-III nitride, for example, GaN and InGaN. Using this technique, it is possible to grow functioning solar cells, yet their potential performance is reduced due to the presence of dislocations (˜10⁸ cm⁻²) that result from heteroepitaxial growth on the sapphire substrate. These dislocations cannot be eliminated due to the lattice mismatch between the group-III nitride layer and the sapphire substrate.

In addition to the generation of inferior material, the properties of sapphire do not allow for significant optimization of the solar cell. The foreign substrate, sapphire, is required for the growth of the group-III nitride material and hence cannot be independently selected or optimized for the functions a solar cell substrate needs to exhibit (transparency, structural qualities, size, electrical conductivity, etc.).

Also, sapphire is not the ideal material if the solar cell is to be illuminated from the backside, i.e., wherein the light is transmitted through the sapphire substrate to strike the group-III nitride material, due to absorption losses and other inadequacies. It is nevertheless desirable to have a substrate material that fulfills the metrics for backside illumination, as this would allow for the creation of novel solar cell structures that efficiently and effectively harvest a larger amount of light and hence energy.

While c-plane growth of group-III nitrides on sapphire is commonly practiced, devices oriented along other crystallographic directions may be preferable for efficient operation of the solar cell. The crystal structure of wurtzite group-III nitrides is such that a polarization field exists within the material primarily along the c-direction. This phenomenon can be an advantage or a disadvantage depending on the electronic structure of the device. Recent research results suggest that growth along a non-polar or semi-polar direction may be preferable to the polar direction (c-direction), as this allows for additional modification and optimization of the solar cell.

Currently, in order to grow a large non-polar or semi-polar group-III nitride solar cell, it is exceedingly difficult to find a suitable foreign substrate that will allow for the growth of a non-polar or semi-polar group-III nitride layer with sufficient quality for the creation of a working solar cell. This has partially to do with the fact that only a selected number of crystallographic planes will grow on certain substrates, but also that these foreign substrates motivate the formation of additional defects (for example, basal plane stacking faults) in addition to the already exceedingly high density of threading dislocations. These defects further reduce device performance.

In almost all cases, it is desirable to directly grow on a high quality group-III nitride material. This material can be obtained from any number of bulk crystal growth techniques, such as HVPE (Hydride Vapor Phase Epitaxy), or true bulk crystal growth techniques, such as the ammonothermal method. Any optimized bulk crystal growth technique will provide a single group-III nitride crystal of significantly better quality.

Moreover, a bulk crystal growth technique generates a large boule, which can be cut along any crystallographic direction, thereby resulting in exceptionally high quality non-polar, semi-polar or polar material. Given sufficient optimization and growth time, any size group-III nitride substrate can be grown, which can be used for the growth of large group-III nitride solar cells.

The downside to this approach is that the bulk group-III nitride material is relatively expensive to manufacture and hence substrate costs will be substantial, significantly increasing the overall cost of the solar cell device. For homoepitaxial growth of a high quality group-III nitride solar cell, however, only a thin, high quality, low defect, highly lattice matched surface layer is needed.

Thus, there is a need in the art for improved methods of fabricating group-III nitride solar cells. The present invention satisfies this need.

### SUMMARY OF THE INVENTION

To overcome the limitations in the prior art described above, and to overcome other limitations that will become apparent upon reading and understanding the present specification, the present invention discloses a method for growing a group-III nitride solar cell on a thin piece of a group-III nitride crystal that has been mounted on a carrier comprised of a foreign material. The thin piece is a thin layer with a thickness that ranges from approximately 5 microns to approximately 300 microns.

### BRIEF DESCRIPTION OF THE DRAWINGS

FIG. 1 is a flowchart that illustrates a method for fabricating a group-III nitride solar cell according to a preferred embodiment of the present invention.

FIG. 2 is a cross-sectional schematic of a group-III nitride solar cell fabricated according to a preferred embodiment of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

Group-III nitride solar cells have been demonstrated that efficiently absorb and convert solar energy to electrical energy. In order to maximize the area these solar cells can cover using the smallest possible amount of material and to be cost effective, the present invention presents a method that allows high quality, large area, group-III nitride solar cells to be produced on cheap substrates, thereby allowing for large area coverage while minimizing the use of expensive materials and maintaining the highest possibly quality. The benefits of large area GaN solar cells that can be achieved with the present invention include lower cost due to reduction in use of expensive material (high quality GaN), and an increase in efficiency due to the ability to use higher quality material than, for example, growth of GaN on a foreign substrate.

Process Steps

Given the benefits of using bulk group-III nitride substrates for the growth of group-III nitride solar cells, it is important to find a way to utilize this high quality material, while minimizing the cost of the material. This invention provides a means to combine the benefits of high quality bulk grown group-III nitride material orientated along any desired direction, while minimizing the overall cost of making a solar cell.

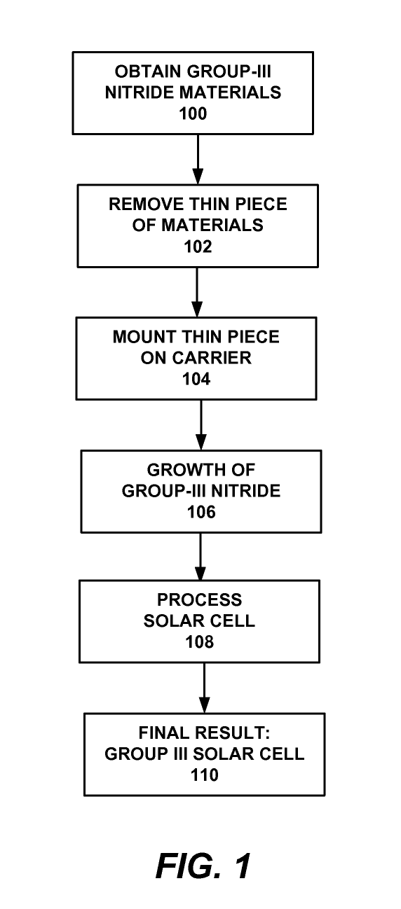

FIG. 1 is a flowchart that illustrates a method for fabricating a group-III nitride solar cell according to a preferred embodiment of the present invention.

Block 100 represents obtaining high quality group-III nitride materials, preferably, a single crystal of low defect density (e.g., <10² cm⁻²).

Block 102 represents removing a thin piece of the group-III nitride crystal.

In this context, the thin piece is a thin layer that has a thickness that ranges, for example, from approximately 5 microns to approximately 300 microns.

The other dimensions of the thin piece are typically as large as possible, for example, from 1″ DIA/rectangular samples, all the way to 12″ DIA/rectangles or larger, wherein the other dimensions are typically limited by the size of high quality group-III nitride material that can be obtained. Moreover, by tiling individual ones of the thin pieces, for example, any size can be achieved.

Preferably, the thin piece from the group-III nitride crystal comprises a group-III nitride material having a higher quality than a group-III nitride layer grown on a typical substrate, for example, a group-III nitride layer grown on a sapphire, spinel or SiC substrate. More specifically, the thin piece from the group-III nitride crystal preferably comprises an InₓGa₁₋ₓN layer where 0<x<1.

Block 104 represents placing and/or mounting the thin piece of the group-III nitride materials onto a suitable carrier material. The suitable carrier material is preferably a foreign material, such as a glass or other amorphous solid (for example, amorphous silicon dioxide), a plastic, a polymer containing material, a metal or metal alloy, a semiconductor, a ceramic, a non-crystalline solid, a poly-crystalline material, or a structure comprising an electronic or optoelectronic device. The foreign material may be a rigid or flexible material, and may be processed in some manner prior to placing the thin piece of the group-III nitride materials upon it. Moreover, the thin piece of the group-III nitride materials is preferably arranged in such a fashion as to increase an effective size of exposed group-III nitride material upon which the group-III nitride solar cell is fabricated.

Block 106 represents fabricating the layers of a group-III nitride solar cell on the thin piece of the group-III nitride materials using any desirable growth technique, including both high and/or low temperature techniques.

These growth techniques may include, for example, epitaxial growth techniques, such as MOCVD (Metal Organic Chemical Vapor Deposition), MBE (Molecular Beam Epitaxy), HVPE, etc., sputtering techniques, or deposition techniques, such as ion beam deposition, laser beam deposition, or electron beam deposition, etc. The growth techniques may also include metal deposition, material deposition, material removal, implantation of chemical elements or species, annealing, baking, etc. Further, flux-based techniques may also be used, for example a sodium flux method.

Preferably, the group-III nitride solar cell is comprised of (Al,B,Ga,In)N semiconductor materials, namely, one or more layers containing GaN, InₓGa₁₋ₓN, AlₓIn₁₋ₓN, AlₓGa₁₋ₓN, Al_{y}Ga_{1-y-x}InₓN or InN. Moreover, one or more of these layers may contain different concentrations of chemical species, such as Si or Mg doping.

Block 108 represents the further processing of the group-III nitride solar cell, if necessary.

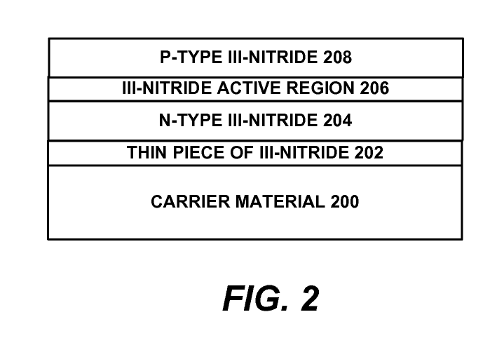

Block 110 represents the end result of the method, namely the group-III nitride solar cell device, which is further described in FIG. 2 below.

It should be noted that the exact sequence of steps in the method can be interchanged or modified depending on the techniques used during each step. Certain techniques, for example, would require the group-III nitride material be mounted onto a carrier material prior to removing a thin piece of the material, rather than removing the thin piece and then mounting it on the carrier material.

Moreover, note the following with regards to the steps of the method.

1. In Block 100, high quality group-III nitride material can be obtained through any desired means, although materials obtained from bulk crystal growth techniques, such an ammonothermal method, sodium flux method, high nitrogen pressure growth method, or congruent melting method, are preferable. Alternatively, bulk group-III nitride materials may be obtained using other techniques, such as HVPE, MOCVD, or MBE, although these techniques typically contain a higher concentration of defects.

2. In Block 102, a thin piece of material can be removed through any desired technique, although it is preferable that the technique maintains the structural quality of the material. One possible technique that can be used to cleave a very thin layer of material from a bulk group-III nitride crystal would be to bombard a prepared surface of the crystal along a desired direction with, for example, H ions (ion implantation), mount the ion-implanted surface onto an amorphous silicon dioxide (glass) carrier wafer, and then perform a thermal anneal, resulting in a separation of a thin layer of high quality GaN material from the bulk single crystal by cleaving while it is still mounted to the carrier wafer, wherein the thin layer comprises the thin piece. Other suitable techniques can also be used, as this invention does not put any limitations on how to obtain a thin piece, i.e., a thin layer, of group-III nitride material that is then mounted onto a carrier wafer, although it may be preferable though to find a technique that reduces kerf losses.

3. Block 104 can be performed before Block 102, if required. Moreover, the actual method of wafer bonding can be optimized for the desired properties needed. For example, it may be advantageous to optimize this wafer bond: to be optically transparent for all wavelengths within a certain window, to be structurally strong, to provide good structural support for the thin group-III nitride material, to be thermally stable for the growth temperature used in Block 106, to be electrically active or passive depending on its integration into the solar cell device and performance, etc.

4. Block 108 includes any and all additional steps required to process the as-grown group-III nitride material into the group-III nitride solar cell. Examples of additional processing steps performed in this Block include: annealing steps, deposition steps to provide antireflection coatings, processing steps to provide metal contacts, etching steps to selectively remove material, surface roughening steps to minimize reflections, etc.

Device Structure

FIG. 2 is a cross-sectional schematic of a group-III nitride solar cell fabricated according to a preferred embodiment of the present invention. FIG. 2 includes a suitable carrier material 200, a thin piece 202 of group-III nitride materials placed and/or mounted onto the suitable carrier material 200, and subsequent device layers, which may include n-type III-nitride layer(s) 204, III-nitride active region(s) 206, and p-type III-nitride layer(s) 208, as well as other device layers.

Possible Modifications and Variations

Many modifications and variations for this invention are possible.

The carrier material can be made of any material, which may be mechanically hard or soft. For example, a structural material such as glass may be used, but an elastic, soft, pliable polymer material could be used as well. The carrier material can be any material that provides the optimal characteristics in terms of, for example, current carrying capacity, transparency, structural properties, improved transmission with reduced reflection (antireflection coatings, etc.). In addition, this foreign carrier material does not have to be lattice matched in any way to the group-III nitride material. This carrier material can be a solar cell comprised of other solar cell materials, such as, but not limited to, Si, GaAs, CdTe, InP, and their alloys.

Additionally, this carrier material can be optimized and processed through other routes prior to being used in Block 104 of FIG. 1. This is particularly of interest, if it is desired to process the carrier material to have anti-reflective coatings or other properties requiring dedicated processing. Note that these processing steps can be performed with the presence of the group-III nitride materials, and hence will not necessarily negatively affect the growth of the group-III nitride solar cell. Additionally, the electrical and optical properties can be tuned to maximize efficiency or any other metric of interest for the resulting solar cell.

While it was previously only mentioned to apply a single thin piece of material onto a carrier wafer, it is possible to tile multiple thin pieces onto the same carrier wafer. By doing so it would be possible to use large production machines for, for example, 8″ wafer diameters using only 2″ diameter group-III nitride wafers. These 2″ wafers could be tiled onto the carrier wafer to approximate an 8″ wafer, thereby further reducing production costs.

Finally, there is no limit on the number of post growth steps incorporated in Block 108 of FIG. 1. Whatever steps are necessary to provide the ultimate result of a high quality group-III nitride solar cell are intended to be part of this invention.

Advantages and Improvements

One particular advantage of this invention is that the carrier wafer can be optimized with antireflection coatings and other performance enhancing techniques, and it is possible to illuminate the group-III nitride solar cell from the back side. This is beneficial in the case of a solar cell that has multiple active regions, wherein each active region is tuned to absorb light higher than a certain energy.

During typical growth of group-III nitride solar cells, InGaN is used as the active region in which the light is converted from solar energy into electrical energy in the form of an electron-hole pairs. The band gap of the alloy determines the lowest energy that can be absorbed. Typically, the higher the energy that needs to be absorbed, the higher the growth temperature needs to be. Under the condition that multiple InGaN layers, each with different In composition, need to be grown, current growth technology suggests that one first grows the layer requiring higher temperature followed by layers that successively require lower growth temperatures. By performing this type of growth, the bottom most layer will absorb, for example, all light with energies in the UV or higher, the following layer in the violet or higher (i.e. including the UV, followed by the blue or higher, and green or higher. Now, if the sunlight is illuminated from the top, all the light from green and higher will be absorbed in the first layer leaving no light for the lower layers to absorb. This is detrimental for solar cells, because it is advantageous to collect light at the highest possible energy and hence voltage. By collecting higher energy light in the lower energy green layer, significant amounts of energy are lost as the voltage at which the higher energy UV light is collected is now the same voltage/energy as the green light (in essence, the energy difference between the green light and UV light is lost as thermal energy). The difference in energy between the UV and green is substantial resulting in an overall loss in efficiency. It is therefore desirable to transmit the light first through the UV layer, then the violet layer, then the blue layer, and then the green layer. This would require backside illumination for which this invention would allow significant optimization.

In addition to the ability to enable improved backside illumination on cheap carrier wafers, it is possible to grow high quality group-III nitride solar cells on an existing monolithic stack of solar cells. In this particular aspect of the invention, it is possible to make use of existing state-of-the-art solar cells using other material systems and further improve on their performance by adding the highest quality GaN solar cell, in addition to the existing capabilities of other types of solar cells, thereby further improving on its performance.

Other advantages to this invention are the reduction in overall absorption losses in the GaN substrate. In typical MOCVD growth of GaN solar cells using GaN substrate, a small portion of the light is lost due to absorption within the bulk GaN substrate in the case of backside illumination. Typical substrate thicknesses are approximately 300 microns, whereas this invention would allow GaN layers on the order of 5 microns. This represents a thickness reduction by a factor of 60, thereby further reducing absorption losses.

Additional advantages include the use of doped GaN layers. Current epitaxial growth techniques for GaN do not allow for significant p-type doping of the GaN layer. While progress has been made to allow for good electrical characteristics, there is still room for improvement. Using this invention, it is possible to utilize a higher p-type doped GaN to be used as the starting point for a high efficiency solar cell. The highly p-type doped GaN layer can be obtained using any desirable bulk growth technique and is no longer restricted to epitaxial growth methods, such as MOCVD, MBE and HVPE. This opens a new parameters space for further improvements.

Another benefit of this invention is that it is easy to produce nitrogen faced GaN solar cells. Current technology using MOCVD allows for growth on sapphire, producing primarily gallium faced, c-plane GaN solar cells. By enabling growth in the opposite direction, it is possible to use the reverse in the polarization field to the device's advantage, along with changes in growth conditions and impurity/dopant incorporations.

It is further advantageous to operate group-III nitride solar cells and higher sunlight concentrations. This can be done by using lenses to focus the sunlight from a larger area onto a smaller area. By doing so, it is possible to further reduce material costs, as cheap materials can be used to collect the sunlight from the large area (mirrors) and concentrated it onto a much smaller area. This smaller area can then be covered by a group-III nitride solar cell. Due to the increased flux of photons, the temperature of the solar cell will increase. By using a custom carrier wafer, it is now possible to improve on the thermal conductivity of the solar cell, thereby providing a means to more easily regulate the temperature of the solar cell, thereby further increasing efficiency.

Nomenclature

The terms “nitride,” “III-nitride,” or “Group-III nitride,” as used herein refer to any alloy composition of the (Al,B,Ga,In)N semiconductors having the formula Al_{w}BₓGa_{y}In_{z}N where 0≦w≦1, 0≦x≦1, 0≦y≦1, and 0≦z≦1. These terms are intended to be broadly construed to include respective nitrides of the single species, Al, B, Ga, and In, as well as binary, ternary and quaternary compositions of such Group III metal species. Accordingly, it will be appreciated that the discussion of the invention hereinafter in reference to GaN and InGaN materials is applicable to the formation of various other (Al,B,Ga,In)N material species. Further, (Al,B,Ga,In)N materials within the scope of the invention may further include minor quantities of dopants and/or other impurity or inclusional materials.

Many III-nitride devices are grown along the polar c-plane of the crystal, although this results in an undesirable quantum-confined Stark effect (QCSE), due to the existence of strong piezoelectric and spontaneous polarizations. One approach to decreasing polarization effects in III-nitride devices is to grow the devices on non-polar or semi-polar planes of the crystal.

The term “non-polar plane” includes the {11-20} planes, known collectively as a-planes, and the {10-10} planes, known collectively as m-planes. Such planes contain equal numbers of Group-III (e.g., gallium) and nitrogen atoms per plane and are charge-neutral. Subsequent non-polar layers are equivalent to one another, so the bulk crystal will not be polarized along the growth direction.

The term “semi-polar plane” can be used to refer to any plane that cannot be classified as c-plane, a-plane, or m-plane. In crystallographic terms, a semi-polar plane would be any plane that has at least two nonzero h, i, or k Miller indices and a nonzero 1 Miller index. Subsequent semi-polar layers are equivalent to one another, so the crystal will have reduced polarization along the growth direction.

Miller indices are a notation system in crystallography for planes and directions in crystal lattices, wherein the notation {hikl} denotes the set of all planes that are equivalent to (hikl) by the symmetry of the lattice. Specifically, the use of braces, {}, denotes a family of symmetry-equivalent planes represented by parentheses, ( ) wherein all planes within a family are equivalent for the purposes of this invention.

Conclusion

This concludes the description of the preferred embodiments of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An optoelectronic device, comprising:
a group-III nitride solar cell grown on a thin piece of a group-III nitride crystal that is mounted on a carrier comprised of a foreign material.

2. The device of claim 1, wherein the thin piece is a thin layer with a thickness that ranges from approximately 5 microns to approximately 300 microns.

3. The device of claim 1, wherein the group-III nitride solar cell is comprised of (Al,B,Ga,In)N.

4. The device of claim 3, wherein the group-III nitride solar cell is comprised of one or more layers containing GaN, InₓGa₁₋ₓN, AlₓIn₁₋ₓN, AlₓGa₁₋ₓN, Al_{y}Ga_{1-y-x}InₓN or InN.

5. The device of claim 3, wherein the group-III nitride solar cell is comprised of one or more layers containing different concentrations of chemical species, such as Si or Mg.

6. The device of claim 1, wherein the thin piece from the group-III nitride crystal has a higher quality than a group-III nitride layer grown on a substrate.

7. The device of claim 6, wherein the thin piece from the group-III nitride crystal comprises an InₓGa₁₋ₓN layer where 0≦x≦1.

8. The device of claim 1, wherein the thin piece from the group-III nitride crystal is arranged in such a fashion as to increase an effective size of exposed group-III nitride material upon which the group-III nitride solar cell is grown.

9. The device of claim 1, wherein the foreign material is comprised of one or more of materials comprising: an amorphous solid, a plastic, a polymer containing material, a metal, a metal alloy, a semiconductor, a ceramic, a non-crystalline solid, a poly-crystalline material, an electronic device, or an optoelectronic device.

10. The device of claim 1, wherein the foreign material is silicon dioxide.

11. The device of claim 1, wherein the foreign material is a flexible material.

12. The device of claim 1, wherein the foreign material is a rigid material.

13. The device of claim 1, wherein the foreign material is processed prior to mounting the thin piece of the group-III nitride crystal on the carrier.

14. A method of fabricating an optoelectronic device, comprising:
growing a group-III nitride solar cell on a thin piece of a group-III nitride crystal that is mounted on a carrier comprised of a foreign material.

15. The method of claim 14, wherein the thin piece is a thin layer with a thickness that ranges from approximately 5 microns to approximately 300 microns.

16. The method of claim 14, wherein the group-III nitride solar cell is comprised of (Al,B,Ga,In)N.

17. The method of claim 16, wherein the group-III nitride solar cell is comprised of one or more layers containing GaN, InₓGa₁₋ₓN, AlₓIn₁₋ₓN, AlₓGa₁₋ₓN, Al_{y}Ga_{1-y-x}InₓN or InN.

18. The method of claim 16, wherein the group-III nitride solar cell is comprised of one or more layers containing different concentrations of chemical species, such as Si or Mg.

19. The method of claim 14, wherein the thin piece from the group-III nitride crystal has a higher quality than a group-III nitride layer grown on a substrate.

20. The method of claim 19, wherein the thin piece from the group-III nitride crystal comprises an InₓGa₁₋ₓN layer where 0≦x≦1.

21. The method of claim 14, wherein the think piece from the group-III nitride crystal is arranged in such a fashion as to increase an effective size of exposed group-III nitride material upon which the group-III nitride solar cell is grown.

22. The method of claim 14, wherein the foreign material is comprised of one or more of materials comprising: an amorphous solid, a plastic, a polymer containing material, a metal, a metal alloy, a semiconductor, a ceramic, a non-crystalline solid, a poly-crystalline material, an electronic device, or an optoelectronic device.

23. The method of claim 14, wherein the foreign material is silicon dioxide.

24. The method of claim 14, wherein the foreign material is a flexible material.

25. The method of claim 14, wherein the foreign material is a rigid material.

26. The method of claim 14, wherein the foreign material is processed prior to mounting the thin piece of the group-III nitride crystal on the carrier.

27. The method of claim 14, wherein the group-III nitride solar cell is grown using one or more techniques comprising: epitaxial growth techniques, sputtering techniques, flux based techniques, or deposition techniques including ion beam deposition, laser beam deposition, or electron beam deposition.

28. The method of claim 14, wherein the growing step includes metal deposition, material deposition, material removal, implantation of chemical elements or species, annealing, or baking
